(19) United States
(12) Patent Application Publication
(10) Pub. No.: US 2024/0304507 A1
(43) Pub. Date: Sep. 12, 2024

(54) Power Semiconductor Package

(71) Applicant: Wolfspeed, Inc., Durham, NC (US)

(72) Inventors: Geza Dezsi, Durham, NC (US); Yusheng Lin, Phoenix, AZ (US); Kuldeep Saxena, Sewickley, PA (US)

(21) Appl. No.: 18/179,036

(22) Filed: Mar. 6, 2023

(51) Int. Cl. H01L 23/31; H01L 23/495; H01L 23/498

(52) U.S. Cl. CPC H01L 23/3107; H01L 23/49555; H01L 23/49562; H01L 23/49811; H01L 24/48; H01L 24/49; H01L 2224/48091; H01L 2224/48175; H01L 2224/49111; H01L 2924/10272; H01L 2924/12032; H01L 2924/13091

(57) ABSTRACT

Power semiconductor packages are provided. In one example, a power semiconductor package may include a power semiconductor die. The power semiconductor package may include a housing having a first side and a second side opposing the first side. The power semiconductor package may include one or more electrical leads extending from the first side. The power semiconductor package may include one or more leadless surface mount type (SMT) connection structures on the second side.

### FIELD

The present disclosure relates generally to semiconductor packages.

### BACKGROUND

Semiconductor devices such as transistors and diodes are ubiquitous in modern electronic devices. Wide band gap semiconductor material systems such as gallium arsenide (GaAs), gallium nitride (GaN), and silicon carbide (SiC) are being increasingly utilized in semiconductor devices to push the boundaries of device performance in areas such as switching speed, power handling capability, and thermal conductivity. Example power semiconductor devices may include metal-oxide-semiconductor field-effect transistors (MOSFETs), insulated gate bipolar transistors (IGBTs), Schottky barrier diodes, PiN diodes, thyristors, and high electron mobility transistors (HEMTs). Packaging technology may play a large role in the performance of power semiconductor devices.

### SUMMARY

Aspects and advantages of embodiments of the present disclosure will be set forth in part in the following description, or may be learned from the description, or may be learned through practice of the embodiments.

One example aspect of the present disclosure is directed to a power semiconductor package. The power semiconductor package may include a power semiconductor die. The power semiconductor package may include a housing having a first side and a second side opposing the first side. The power semiconductor package may include one or more electrical leads extending from the first side. The power semiconductor package may include one or more leadless surface mount type (SMT) connection structures on the second side.

Another example aspect of the present disclosure is directed to a power semiconductor package. The power semiconductor package may include a semiconductor die. The power semiconductor package may include a housing having a first side and a second side opposing the first side. The power semiconductor package may include one or more electrical leads extending from the first side. The power semiconductor package may include one or more SMT connection structures on the second side. Each of the one or more SMT connection structures may have a connection surface area that is greater than a connection surface area of the one or more electrical leads.

Another example aspect of the present disclosure is directed to a power semiconductor package. The power semiconductor package may include a semiconductor die. The power semiconductor package may include a housing having a first side and a second side opposing the first side. The housing having a first surface extending between the first side and the second side and a second surface opposing the first surface. The power semiconductor package may include a thermal pad. The power semiconductor package may include a step structure on the first surface of the housing. The step structure may be defined in the housing such that a first portion of the housing at the first side has a first thickness and a second portion of the housing at the thermal pad has a second thickness. The second thickness may be greater than the first thickness.

Another example aspect of the present disclosure is directed to a method. The method may include providing a first power semiconductor package. The first power semiconductor package may include a first housing having a first side and a second side opposing the first side. The first power semiconductor package may include one or more first electrical leads extending from the first side, and one or more first leadless surface mount type (SMT) connection structures on the second side. The method may include providing a second power semiconductor package. The second power semiconductor package may include a second housing having a third side and a fourth side opposing the third side. The second power semiconductor package may include one or more second electrical leads extending from the third side, and one or more second leadless SMT connection structures on the fourth side. The second side of the first power semiconductor package may be aligned with the fourth side of the second power semiconductor package.

Another example aspect of the present disclosure is directed to a power semiconductor package assembly. The power semiconductor package assembly may include a first power semiconductor package. The first power semiconductor package may include a first housing having a first side and a second side opposing the first side. The first power semiconductor package may include one or more first electrical leads extending from the first side, and one or more first leadless surface mount type (SMT) connection structures on the second side. The power semiconductor package assembly may include a second power semiconductor package. The second power semiconductor package may include a second housing having a third side and a fourth side opposing the third side. The second power semiconductor package may include one or more second electrical leads extending from the third side, and one or more second leadless SMT connection structures on the fourth side. The second side of the first power semiconductor package may be aligned with the fourth side of the second power semiconductor package.

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which:

FIG. 1 depicts a top perspective view of a semiconductor package according to example embodiments of the present disclosure;

FIG. 2 depicts a bottom perspective view of a semiconductor package according to example embodiments of the present disclosure;

FIG. 3 depicts a bottom perspective view of a semiconductor package with portions of the semiconductor package being transparent according to example embodiments of the present disclosure;

FIG. 4 depicts a top perspective view of a semiconductor package according to example embodiments of the present disclosure;

FIG. 5 depicts a bottom perspective view of a semiconductor package according to example embodiments of the present disclosure;

FIG. 6 depicts a side view of a semiconductor package according to example embodiments of the present disclosure;

FIG. 7 depicts a bottom perspective view of a semiconductor package with portions of the semiconductor package being transparent according to example embodiments of the present disclosure;

FIG. 8 depicts a top perspective view of a semiconductor package according to example embodiments of the present disclosure;

FIG. 9 depicts a top perspective view of a semiconductor package according to example embodiments of the present disclosure;

FIG. 10 depicts a top perspective view of a semiconductor package according to example embodiments of the present disclosure;

FIG. 11 depicts a top perspective view of a semiconductor package with portions of the semiconductor package being transparent according to example embodiments of the present disclosure;

FIG. 12 depicts a top perspective view of an example semiconductor package assembly according to example embodiments of the present disclosure;

FIG. 13 depicts a bottom perspective view of an example semiconductor package assembly according to example embodiments of the present disclosure;

FIG. 14 depicts a flow chart of an example method according to example embodiments of the present disclosure; and

FIG. 15 depicts example separation of an example semiconductor package assembly according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Discrete semiconductor packages have been developed that include a semiconductor die, such as a MOSFET or a Schottky diode. Such semiconductor packages with MOSFETs may be employed in a variety of applications to enable higher switching frequencies along with reduced associated losses, higher blocking voltages, and improved avalanche capabilities. Example applications may include high performance industrial power supplies, server/telecom power, electric vehicle charging systems, energy storage systems, uninterruptible power supplies, high-voltage DC/DC converters, electric vehicles, and battery management systems. Discrete semiconductor packages with Schottky diodes may be employed in many of the same high-performance power applications described above for MOSFETs, sometimes in systems that also include discrete power packages of MOSFETs.

Packaging technology for semiconductor devices plays an important role in defining the performance of the semiconductor devices. For example, the packaging of a power semiconductor die may limit the ability of the semiconductor die to dissipate heat, conduct current, or even switch at particular speeds (e.g., due to stray inductance). Ineffective heat dissipation can create problems for semiconductor devices (e.g., small form factor semiconductor devices) or in situations where the semiconductor device comes into close contact with the housing. Excessive heat can adversely impact the operation of the semiconductor device itself, as well as the electronic system that uses that semiconductor device.

Example aspects of the present disclosure are directed to semiconductor packages that incorporate surface mount technology (SMT) structures. The semiconductor packages may provide enhanced flexibility with different pin out options for electrical leads. In some embodiments, the semiconductor packages may include a thermal pad for topside cooling which may allow for direct attachment to a heat sink (e.g., with an electrical isolator) to enhance thermal performance. The semiconductor package may provide for increased current and voltage handling capabilities relative to other semiconductor packages with small form factors.

In some embodiments, the power semiconductor package may include a semiconductor die. The semiconductor die may be based on a wide band gap semiconductor material. A wide band gap semiconductor has a band gap greater than about 1.40 eV, such as silicon carbide and/or a Group III-nitride (e.g., gallium nitride). In some examples, the semiconductor die may include semiconductor devices, such as transistors, diodes, and/or thyristors. For instance, in some examples, the power semiconductor die may include silicon carbide-based MOSFETs located between a source contact and a drain contact to form, for instance, a vertical structure power semiconductor device.

Aspects of the present disclosure are discussed with reference to silicon carbide-based MOSFET devices for purposes of illustration and discussion. Those of ordinary skill in the art, using the disclosures provided herein, will understand that the power semiconductor die may include other power semiconductor devices without deviating from the scope of the present disclosure, such as diodes (e.g., Schottky diodes, PiN diodes, etc.), insulated gate bipolar transistors, high electron mobility transistors, or other devices.

In some examples, the power semiconductor package may include a housing having a first side and a second side that is opposing the first side. The power semiconductor package may include one or more electrical leads extending from the first side. The power semiconductor package may include one or more surface mount type (SMT) connection structures on the second side. The SMT connection structures may have a size that is larger than the one or more electrical leads. For instance, the SMT connection structures may have a larger connection surface relative to each of the one or more electrical leads. More particularly, the SMT connection structures may each have a connection surface area that is greater than a connection surface area of each of the one or more electrical leads, such as at least two times greater, such as at least 2.5 times greater, such as at least three times greater.

In some examples, because of the smaller size of the electrical leads relative to the SMT connection structures, the first side may have a greater number of electrical leads relative to the number of SMT connection structures on the second side. For instance, in some examples, the power semiconductor package may have two SMT connection structures on the second side and two to fourteen electrical leads on the first side. In this way, the power semiconductor package may accommodate a high-power rating (e.g., high voltage rating) through the use of the SMT connection structures with high connection surface area, while still accommodating flexibility in providing other connections (e.g., gate, source, kelvin, sensor) through the smaller electrical leads.

In some examples, the one or more SMT connection structures may be leadless SMT connection structures. For example, the SMT connection structures may be wettable flank connection structures. In these examples, the SMT connection structures may be partially encapsulated in the housing such that a connection surface of the wettable flank connection structure is exposed through a mounting surface of the housing. The wettable flank connection structure may also be exposed through at least one side surface of the housing. This may facilitate connection of the power semiconductor package to other structures (e.g., a circuit board) and may facilitate efficient design of a lead frame (e.g., conductive lead frame) for the power semiconductor package.

In some examples, the one or more SMT connection structures may be SMT connection tabs. The one or more SMT connection tabs may extend from the second side of the housing. The one or more SMT connection tabs may extend from the second side of the housing at a location below a top surface of the housing (e.g., a surface opposite the mounting surface).

In some examples, the power semiconductor package may include a thermal pad. The thermal pad may provide for cooling of the semiconductor package (e.g., topside cooling). In some examples, the power semiconductor package may include a creepage extension structure between the thermal pad and the first side of the power semiconductor package. The creepage extension structure may increase the current and voltage handling capability of the power semiconductor package. More particularly, the creepage extension structure may increase voltage isolation between the one or more electrical leads on the first side of the housing and the SMT connection structures on the second side of the housing. The creepage extension structure may effectively increase a surface distance (e.g., creepage distance) along the housing of the power semiconductor package between the one or more electrical leads on the first side of the housing and the SMT connection structures on the second side of the housing.

In some examples, the creepage extension structure may include a step structure between the one or more electrical leads and the thermal pad. Alternatively or in addition, the creepage extension structure may include a step structure between the thermal pad and the one or more SMT connection structures. The step structure may have a depth of about 0.5 mm to about 2.0 mm.

In some examples, the creepage extension structure may include one or more trenches defined in the housing. The one or more trenches may be defined between the step structure and the one or more electrical leads extending from the first side of the housing. The one or more trenches may extend at least partially along a peripheral edge of the housing at the first side of the housing. The one or more trenches may have a depth of about 0.5 mm to about 2.0 mm and a length of about 5 mm to about 10 mm. The creepage extension structure may provide a creepage distance between the one or more electrical leads and the SMT connection structures of about 5 mm to about 20 mm.

In some embodiments, the power semiconductor package may provide electrical isolation between the thermal pad and the one or more SMT connection structures. For instance, the thermal pad may be on a first side of an insulating layer of a mounting substrate for the semiconductor die. The SMT connection structures and/or conductive lead frame coupled to the SMT connection structures may be coupled to one or more conductive pads on a second side of the insulating layer of the mounting substrate such that the insulating layer is disposed between the SMT connection structures and the thermal pad. In some examples, the mounting substrate may be, for instance, a directed bonded copper (DBC) substrate or an active metal brazed (AMB) substrate.

Aspects of the present disclosure provide a number of technical effects and benefits. For instance, the power semiconductor package may provide efficient thermal dissipation through a thermal pad. The power semiconductor package may provide for multiple pin options for the electrical leads extending from the power semiconductor package, making the power semiconductor package suitable for use with multiple device families. The power semiconductor package may have a high voltage and/or a high current rating due to the use of large SMT connection structures (e.g., for connection to the source and/or drain) and due to, for instance, the creepage extension structure. The power semiconductor package may provide a small form factor. The power semiconductor package may provide for electrical isolation between the thermal pad and the SMT connection structures (e.g., drain connection).

It will be understood that, although the terms first, second, third, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there are no intervening elements present, except in some examples an attach material (e.g., die-attach material, solder, paste, adhesive, sintered material or other material may be present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present, except in some examples an attach material (e.g., die-attach material, solder, paste, adhesive, sintered material or other material may be present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments of the disclosure. The thickness of layers and regions in the drawings may be exaggerated for clarity. Additionally, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

Aspects of the present disclosure are discussed with reference to silicon carbide-based semiconductor structures, such as silicon carbide-based MOSFETs. Those of ordinary skill in the art, using the disclosures provided herein, will understand that the power semiconductor packages according to example embodiments of the present disclosure may be used with any semiconductor material, such as other wide band gap semiconductor materials, without deviating from the scope of the present disclosure. Example wide band gap semiconductor materials include silicon carbide (e.g., 2.996 eV band gap for alpha silicon carbide at room temperature) and the Group III-nitrides (e.g., 3.36 cV band gap for gallium nitride at room temperature).

In the drawings and specification, there have been disclosed typical embodiments and, although specific terms are employed, they are used in a generic and descriptive sense only and not for purposes of limitation of the scope set forth in the following claims.

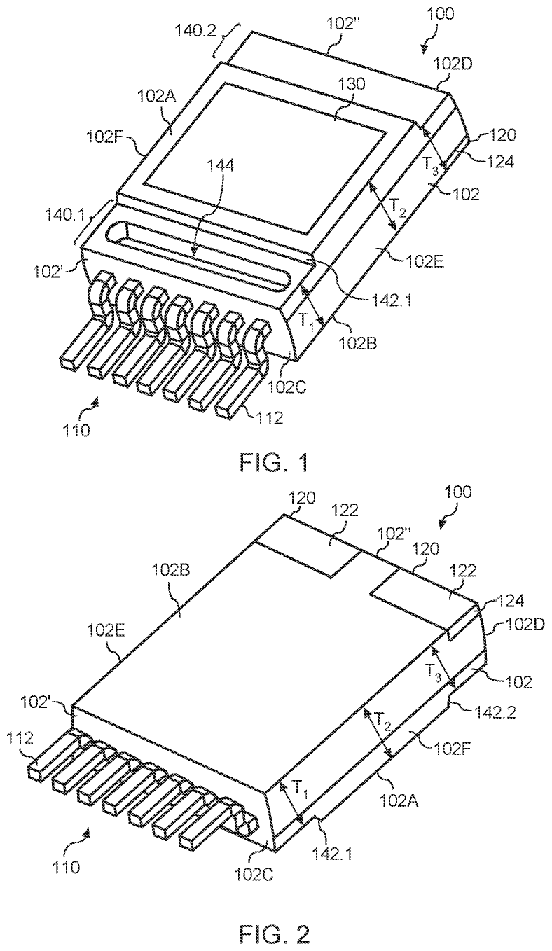

FIG. 1 depicts a top perspective view of an example semiconductor package 100 according to example embodiments of the present disclosure. FIG. 2 depicts a bottom perspective view of the example semiconductor package 100. With reference to FIGS. 1 and 2, the semiconductor package 100 includes a housing 102. The semiconductor package 100 may be arranged to house and provide external electrical connections to a semiconductor die that is located within the housing 102, such as a semiconductor die having a MOSFET or a Schottky diode.

The housing 102 may include a first side 102′ and an opposing second side 102″. The housing 102 may include a first surface 102A (e.g., a top surface) extending between the first side 102′ and the second side 102″. The housing 102 may include a second surface 102B (e.g., a bottom surface or mounting surface) extending between the first side 102′ and the second side 102″. The housing 102 may also include side surfaces 102C, 102D, 102E, and 102F. The side surface 102C may be located at the first side 102′. The side surface 102D may be located at the second side 102″. The housing 102 may include different arrangements of surfaces without deviating from the scope of the present disclosure. For instance, one or more notches or recesses may be formed in any of the surface 102A-102F without deviating from the scope of the present disclosure.

The power semiconductor package 100 may be arranged as a surface mount technology (SMT) package with the first surface 102A (e.g., top surface) positioned opposite an external surface, such as a printed circuit board (PCB) on which the power semiconductor package 100 is mounted. The second surface 102B (e.g., bottom surface or mounting surface) forms a mounting side of the power semiconductor package 100 that is mounted to the external surface, such as a PCB.

The housing 102 may be formed by a molding process. The housing 102 may include a material capable of high temperature operation, such as a temperature of about 200° C. Example materials for the housing 102 may include an epoxy material or an epoxy mold compound (EMC).

The power semiconductor package 100 includes one or more electrical leads 110 extending from the first side 102′ of the housing 102. The electrical leads 110 may be SMT connection structures having a connection surface 112. The connection surface 112 of the electrical leads 110 may be used to connect internal components of the power semiconductor package 100 to external electrical connections. The electrical leads 110 have the form of electrical connection pins.

The power semiconductor package 100 includes leadless SMT connection structures 120 on the second side 102″ of the housing 102. The leadless SMT connection structures 120 have a connection surface 122. A surface area of the connection surface 122 of the leadless SMT connection structures 120 may be greater than a surface area of the connection surface 112 of the electrical leads 110 (e.g., electrical connection pins), such as about two times greater, such as about 2.5 times greater, such as about three times greater.

In the example power semiconductor package 100 of FIGS. 1 and 2, the leadless SMT connection structures 120 are wettable flank connection structures. More particularly, the leadless SMT connection structures 120 are partially encapsulated by the housing 102 such that the connection surface 122 of the leadless SMT connection structures 120 are exposed through the second surface 102B (e.g., the mounting surface) of the power semiconductor package 100. In some examples, the connection surface 122 of each leadless SMT connection structure 120 is coplanar with the second surface 102B (e.g., the mounting surface). In some examples, a portion 124 of each leadless SMT connection structure 120 is exposed through the side surfaces 102D, 102E or side surfaces 102D, 102F of the housing 102.

As illustrated, a number of electrical leads 110 extending from the first side 102′ of the housing 102 may be greater than a number of leadless SMT connection structures 120 on the second side 102″ of the housing 102. For instance, the power semiconductor package 100 includes seven electrical leads 110 and two leadless SMT connection structures 120. More or fewer electrical leads 110 may be included in the power semiconductor package 100 without deviating from the scope of the present disclosure. More or fewer leadless SMT connection structures 120 may be included in the power semiconductor package 100 without deviating from the scope of the present disclosure.

Referring still to FIGS. 1 and 2, the first surface 102A (e.g., the top surface) of the housing 102 may include a thermal pad 130. The thermal pad 130 may include a thermally conductive material, such as a metal. The thermal pad 130 may be coupled to an external heat sink (e.g., with an electrical isolator) to provide topside cooling for the power semiconductor package 100.

The first surface 102A of the housing 102 may also include creepage extension structures 140.1 and 140.2. The creepage extension structures 140.1 and 140.2 may increase a creepage distance between the electrical leads 110 and the leadless SMT connection structures 120. In the example of FIGS. 1 and 2, the creepage extension structure 140.1 includes a first step structure 142.1 between the thermal pad 130 and the electrical leads 110 extending from the first side 102′ of the housing 102. The first step structure 142.1 may be defined such that the housing 102 has a first thickness T₁ at the first side 102′ of the housing 102 and a second thickness T₂ at the thermal pad 130. The second thickness T₂ is greater than the first thickness T₁. For instance, the step structure may have a depth in a range of about 0.5 mm to about 2.0 mm such that T₂ exceeds T₁ by about 0.5 mm to about 2.0 mm.

The creepage extension structure 140.2 includes a second step structure 142.2 between the thermal pad 130 and the leadless SMT connection structures 120 on the second side 102″ of the housing 102. The second step structure 142.2 may be defined such that the housing 102 has a third thickness T₃ at the second side 102″ of the housing 102 and a second thickness T₂ at the thermal pad 130. The second thickness T₂ is greater than the third thickness T₃. For instance, the second step structure may have a depth in a range of about 0.1 mm to about 2.5 mm such that T₂ exceeds T₃ by about 0.1 mm to about 2.5 mm. The third thickness T₃ may be the same as or different from the first thickness T₁. The second step structure 142.2 may have a depth that is the same as or different from the depth of the first step structure 142.1.

The housing 102 of the power semiconductor package 100 may have other creepage extension features without deviating from the scope of the present disclosure. For instance, the first creepage extension structure 140.1 may include a trench 144 defined along a peripheral edge of the housing 102 at the first side 102′ of the housing 102 between the electrical leads 110 and the thermal pad 130. The trench 144 may have a depth in a range of, for instance, 0.5 mm to about 2.0 mm. The total creepage distance between the electrical leads 110 and the leadless SMT connection structures 120 may be, for instance, in a range of about 5 mm to about 20 mm.

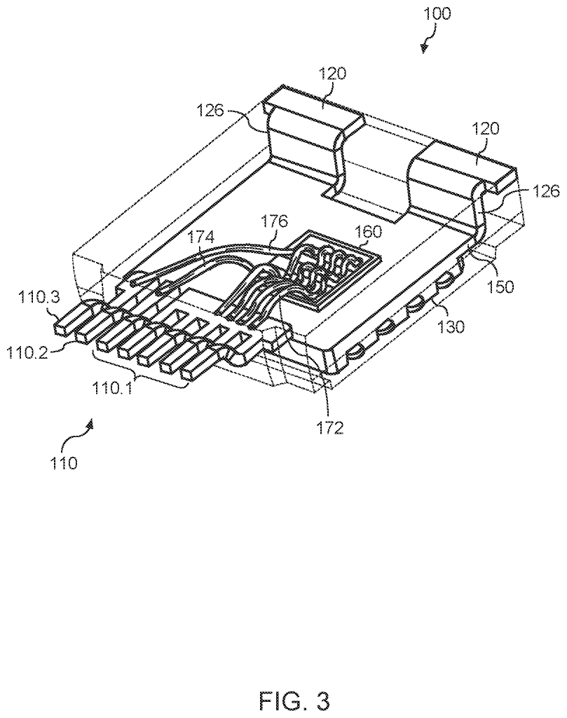

FIG. 3 depicts a bottom perspective view of the power semiconductor package 100 with the housing 102 transparent according to example embodiments of the present disclosure. As illustrated, a semiconductor die 160 may be mounted on a mounting substrate 150 (e.g., conductive lead frame) for the power semiconductor package. The mounting substrate 150 may be coupled to or integral with the thermal pad 130. The semiconductor die 160 may be attached to the mounting substrate 150, for instance, using a die-attach material.

The semiconductor die 160 may include one or more semiconductor devices, such as MOSFET devices, Schottky diodes, or other devices. In some examples, the semiconductor die 160 may be based on a wide band gap semiconductor, such as silicon carbide and/or a Group III-nitride (e.g., gallium nitride). For instance, in some examples, the power semiconductor die 160 may include silicon carbide-based MOSFETs located between a source contact and a drain contact to form, for instance, a vertical structure power semiconductor device. Aspects of the present disclosure are discussed with reference to silicon carbide-based MOSFET devices for purposes of illustration and discussion. Those of ordinary skill in the art, using the disclosures provided herein, will understand that the power semiconductor die may include other power semiconductor devices without deviating from the scope of the present disclosure, such as diodes (e.g., Schottky diodes, PiN diodes, etc.), insulated gate bipolar transistors, high electron mobility transistors, or other devices.

The semiconductor die 160 may be, for instance, a 7 mm by 7 mm semiconductor die. However, aspects of the present disclosure are applicable to many different semiconductor die sizes, such as 1 mm by 1 mm semiconductor die to 7 mm by 9 mm semiconductor die, as some examples.

In the example of a semiconductor die 160 including a silicon carbide-based MOSFET device, the electrical leads 110 may include a first lead 110.1, a second lead 110.2, and a third lead 110.3. The first lead 110.1 may include a plurality of integral electrical connection pins. The first lead 110.1 may be coupled to a source of the MOSFET device on the semiconductor die 160 using, for instance, wire bonds 172. The first lead 110.1 may be used to connect the source of the MOSFET device on the semiconductor die 160 to one or more external connections (e.g., on a PCB).

The second lead 110.2 may include an electrical connection pin (e.g., a single electrical connection pin). The second lead 110.2 may be coupled to a gate of the MOSFET device on the semiconductor die 160 using, for instance, wire bond 174. The second lead 110.2 may be used to connect the gate of the MOSFET device on the semiconductor die 160 to one or more external connections (e.g., on a PCB).

The third lead 110.3 may include an electrical connection pin (e.g., a single electrical connection pin). The third lead 110.3 may be coupled to another contact associated with the MOSFET device on the semiconductor die 160, such as a source-kelvin contact and/or a sensor contact. The third lead 110.3 may be coupled to a gate of the MOSFET device on the semiconductor die 160 using, for instance, wire bond 176. The third lead 110.3 may be used to connect the contact associated with the MOSFET device on the semiconductor die 160 to one or more external connections (e.g., on a PCB).

The SMT connection structures 120 may be connected to a drain of the MOSFET device on the semiconductor die 160. More particularly, the drain of the MOSFET device may be electrically coupled (e.g., through a die-attach material) to the mounting substrate 150. The SMT connection structures 120 may be electrically coupled to the mounting substrate 150. For instance, the SMT connection structures 120 may be electrically coupled to the mounting substrate 150 through connection elbows 126. The connection elbows 126 and/or the SMT connection structures 120 may be integral with the mounting substrate 150 in some embodiments.

As discussed above, the power semiconductor package 100 may include a semiconductor die 160 with other types of semiconductor devices without deviating from the scope of the present disclosure. For instance, in some examples, the semiconductor die 160 may include a Schottky diode. In this example, one or more of the electrical leads 110 may be coupled to a first contact of the Schottky diode on the semiconductor die 160 using, for instance, wire bonds. The SMT connection structures 120 may be connected to a second contact of the Schottky diode, for instance, through the mounting substrate 150 (e.g., through the connection elbows 126 and mounting substrate 150).

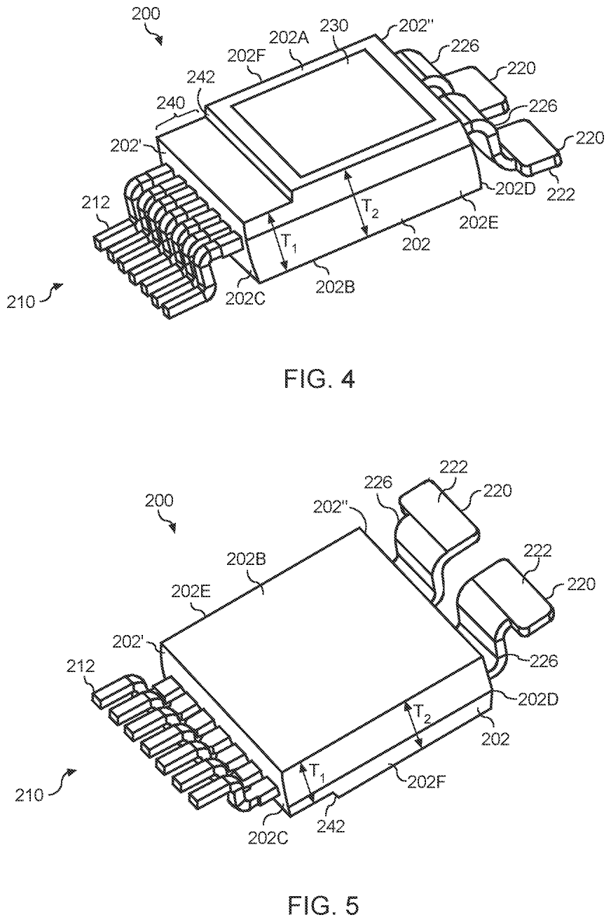

FIG. 4 depicts a top perspective view of an example semiconductor package 200 according to example embodiments of the present disclosure. FIG. 5 depicts a bottom perspective view of the example semiconductor package 200. With reference to FIGS. 4 and 5, the semiconductor package 200 includes a housing 202. The semiconductor package 200 may be arranged to house and provide external electrical connections to a semiconductor die that is located within the housing 202, such as a semiconductor die having a MOSFET or a Schottky diode.

The housing 202 may include a first side 202′ and an opposing second side 202″. The housing 202 may include a first surface 202A (e.g., a top surface) extending between the first side 202′ and the second side 202″. The housing 202 may include a second surface 202B (e.g., a bottom surface or mounting surface) extending between the first side 202′ and the second side 202″. The housing 202 may also include side surfaces 202C. 202D, 202E, and 202F. The side surface 202C may be located at the first side 202′. The side surface 202D may be located at the second side 202″. The housing 202 may include different arrangements of surfaces without deviating from the scope of the present disclosure. For instance, one or more notches or recesses may be formed in any of the surface 202A-202F without deviating from the scope of the present disclosure.

The power semiconductor package 200 may be arranged as a surface mount technology (SMT) package with the first surface 202A (e.g., top surface) positioned opposite an external surface, such as a printed circuit board (PCB) on which the power semiconductor package 200 is mounted. The second surface 202B (e.g., bottom surface or mounting surface) forms a mounting side of the power semiconductor package 200 that is mounted to the external surface, such as a PCB.

The housing 202 may be formed by a molding process. The housing 202 may include a material capable of high temperature operation, such as a temperature of about 200° C. Example materials for the housing 202 may include an epoxy material or an epoxy mold compound (EMC).

The power semiconductor package 200 includes one or more electrical leads 210 extending from the first side 202′ of the housing 202. The electrical leads 210 may be SMT connection structures having a connection surface 212. The connection surface 212 of the electrical leads 210 may be used to connect internal components of the power semiconductor package 200 to external electrical connections. The electrical leads 210 have the form of electrical connection pins.

The power semiconductor package 200 includes SMT connection structures 220 on the second side 102″ of the housing 102. The SMT connection structures 220 have a connection surface 222. A surface area of the connection surface 222 of the SMT connection structures 220 may be greater than a surface area of the connection surface 212 of the electrical leads 210 (e.g., electrical connection pins), such as about two times greater, such as about 2.5 times greater, such as about three times greater.

In the example power semiconductor package 200 of FIGS. 3 and 4, the SMT connection structures 220 are SMT connection tabs 220. The SMT connection tabs 220 extend from the second side 202″ of the housing 202 (e.g., extend from the side surface 202). The SMT connection tabs 220 each include the connection surface 222 and a connection elbow 226. The connection elbow 226 may be integral with the connection surface 222. The housing 202 does not encapsulate at least a portion of the connection elbow 226 such that the connection elbow 226 is exposed.

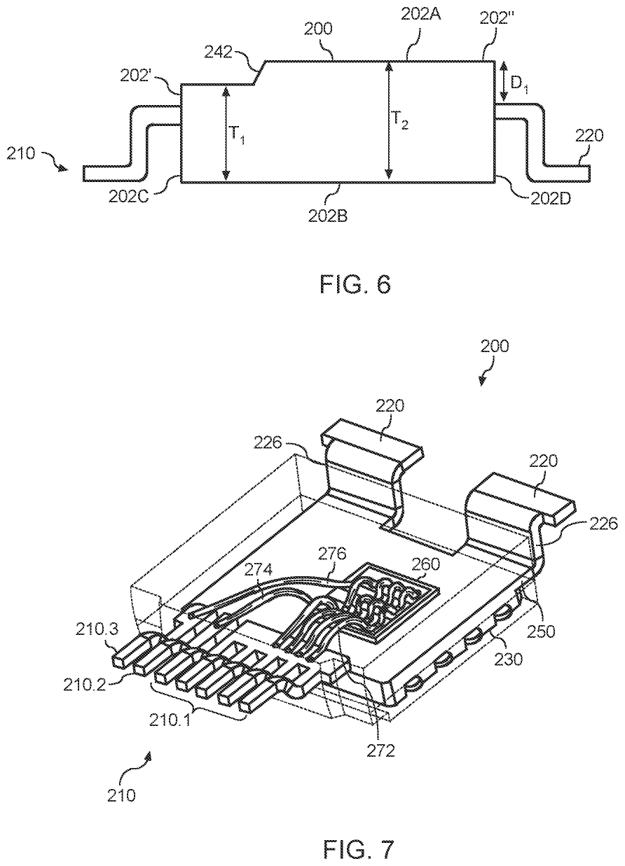

In some examples, the SMT connection tabs 220 extend from the second side 202″ of the housing 202 at a location below the top surface 202A of the housing 202. For instance, FIG. 6 depicts a side view of the example power semiconductor package 200 according to example embodiments of the present disclosure. As shown, the SMT connection tabs 220 extend from the side surface 202D at the second side 202″ of the housing 202 at a location below the top surface 202A of the housing 202, such as at a depth D1 below the top surface 202A of the housing 202. The depth D1 may be in a range of, for instance, 0.5 mm to about 2.0 mm. In some examples, the connection surface 222 of each of the SMT connection tabs 220 may be coplanar with the bottom surface 202B of the housing 202 of the power semiconductor package 200.

Referring back to FIGS. 4 and 5, a number of electrical leads 210 extending from the first side 202′ of the housing 202 may be greater than a number of SMT connection structures 220 extending from the second side 202″ of the housing 202. For instance, the power semiconductor package 200 includes seven electrical leads 210 and two SMT connection structures 220. More or fewer electrical leads 210 may be included in the power semiconductor package 200 without deviating from the scope of the present disclosure. More or fewer SMT connection structures 220 may be included in the power semiconductor package 200 without deviating from the scope of the present disclosure.

Referring still to FIGS. 4 and 5, the first surface 202A (e.g., the top surface) of the housing 202 may include a thermal pad 230. The thermal pad 230 may include a thermally conductive material, such as a metal. The thermal pad 230 may be coupled to an external heat sink (e.g., with an electrical isolator) to provide topside cooling for the power semiconductor package 300.

The first surface 202A of the housing 202 may also include a creepage extension structure 240. The creepage extension structure 240 may increase a creepage distance between the electrical leads 210 and the SMT connection structures 220. In the example of FIGS. 4 and 5, the creepage extension structure 240 includes a step structure 242 between the thermal pad 230 and the electrical leads 210 extending from the first side 202′ of the housing 202. The step structure 242 may be defined such that the housing 202 has a first thickness T₁ at the first side 202′ of the housing 202 and a second thickness T₂ at the second side 202″ of the housing 202. The second thickness T₂ is greater than the first thickness T₁. For instance, the step structure may have a depth in a range of about 0.5 mm to about 2.0 mm such that T₂ exceeds T₁ by about 0.5 mm to about 2.0 mm. The housing 202 of the power semiconductor package 200 may have other creepage extension features without deviating from the scope of the present disclosure.

FIG. 7 depicts a bottom perspective view of the power semiconductor package 200 with the housing 202 transparent according to example embodiments of the present disclosure. As illustrated, a semiconductor die 260 may be mounted on a mounting substrate 250 (e.g., conductive lead frame) for the power semiconductor package. The mounting substrate 250 may be coupled to or integral with the thermal pad 230. The semiconductor die 260 may be attached to the mounting substrate 250, for instance, using a die-attach material.

The semiconductor die 260 may include one or more semiconductor devices, such as MOSFET devices, Schottky diodes, or other devices. In some examples, the semiconductor die 260 may be based on a wide band gap semiconductor, such as silicon carbide and/or a Group III-nitride (e.g., gallium nitride). For instance, in some examples, the power semiconductor die 260 may include silicon carbide-based MOSFETs, located between a source contact and a drain contact to form, for instance, a vertical structure power semiconductor device. Aspects of the present disclosure are discussed with reference to silicon carbide-based MOSFET devices for purposes of illustration and discussion. Those of ordinary skill in the art, using the disclosures provided herein, will understand that the power semiconductor die may include other power semiconductor devices without deviating from the scope of the present disclosure, such as diodes (e.g., Schottky diodes, PiN diodes, etc.), insulated gate bipolar transistors, high electron mobility transistors, or other devices.

The semiconductor die 260 may be, for instance, a 7 mm by 7 mm semiconductor die. However, aspects of the present disclosure are applicable to many different semiconductor die sizes, such as 1 mm by 1 mm semiconductor die to 7 mm by 9 mm semiconductor die, as some examples.

In the example of a semiconductor die 260 including a silicon carbide-based MOSFET device, the electrical leads 210 may include a first lead 210.1, a second lead 210.2, and a third lead 210.3. The first lead 210.1 may include a plurality of integral electrical connection pins. The first lead 210.1 may be coupled to a source of the MOSFET device on the semiconductor die 260 using, for instance, wire bonds 272. The first lead 210.1 may be used to connect the source of the MOSFET device on the semiconductor die 260 to one or more external connections (e.g., on a PCB).

The second lead 210.2 may include an electrical connection pin (e.g., a single electrical connection pin). The second lead 210.2 may be coupled to a gate of the MOSFET device on the semiconductor die 260 using, for instance, wire bond 274. The second lead 210.2 may be used to connect the gate of the MOSFET device on the semiconductor die 260 to one or more external connections (e.g., on a PCB).

The third lead 210.3 may include an electrical connection pin (e.g., a single electrical connection pin). The third lead 210.3 may be coupled to another contact associated with the MOSFET device on the semiconductor die 260, such as a source-kelvin contact and/or a sensor contact. The third lead 210.3 may be coupled to a gate of the MOSFET device on the semiconductor die 260 using, for instance, wire bond 276. The third lead 210.3 may be used to connect the contact associated with the MOSFET device on the semiconductor die 260 to one or more external connections (e.g., on a PCB).

The SMT connection structures 220 may be connected to a drain of the MOSFET device on the semiconductor die 260. More particularly, the drain of the MOSFET device may be electrically coupled (e.g., through a die-attach material) to the mounting substrate 250. The SMT connection structures 220 may be electrically coupled to the mounting substrate 250. For instance, the SMT connection structures 220 may be electrically coupled to the mounting substrate 150 through connection elbows 226. The connection elbows 226 and/or the SMT connection structures 120 may be integral with the mounting substrate 250 in some embodiments.

As discussed above, the power semiconductor package 200 may include a semiconductor die 260 with other types of semiconductor devices without deviating from the scope of the present disclosure. For instance, in some examples, the semiconductor die 260 may include a Schottky diode. In this example, one or more of the electrical leads 210 may be coupled to a first contact of the Schottky diode on the semiconductor die 260 using, for instance, wire bonds. The SMT connection structures 220 may be connected to a second contact of the Schottky diode, for instance, through the mounting substrate 250 (e.g., through the connection elbows 126 and mounting substrate 250).

Variations and modifications may be made to the example power semiconductor devices described herein without deviating from the scope of the present disclosure. For instance, the power semiconductor devices may include electrical leads extending from the first side of the power semiconductor die of varying size and shape.

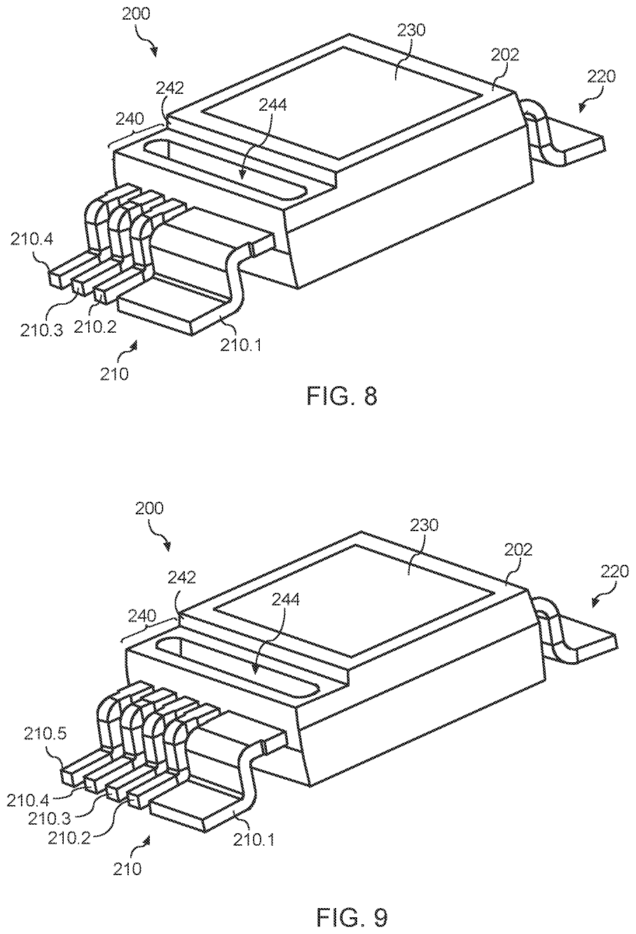

For instance, FIG. 8 depicts the example power semiconductor package 200 of FIGS. 4 and 5 with a different arrangement of electrical leads 210 according to example embodiments of the present disclosure. The example power semiconductor package 200 of FIG. 8 includes four electrical leads 210, namely a first lead 210.1, a second lead 210.2, a third lead 210.3, and a fourth lead 210.4. The first lead 210.1 can have a larger size relative to the second lead 210.2, third lead 210.3, and fourth lead 210.4. In addition, in the example of FIG. 8, the power semiconductor device 200 may include a trench 244 as part of the creepage extension structure 240 for the power semiconductor package 200. The trench 244 may be defined along a peripheral edge of the housing 202 at the first side 202′ of the housing 202 between the electrical leads 210 and the thermal pad 230. The trench 244 may have a depth in a range of, for instance, 0.5 mm to about 2.0 mm.

FIG. 9 depicts the example power semiconductor package 200 of FIGS. 4 and 5 with another arrangement of electrical leads 210 according to example embodiments of the present disclosure. The example power semiconductor package 200 of FIG. 9 includes five electrical leads 210, namely a first lead 210.1, a second lead 210.2, a third lead 210.3, a fourth lead 210.4, and a fifth lead 210.5. The first lead 210.1 can have a larger size relative to the second lead 210.2, third lead 210.3, fourth lead 210.4, and fifth lead 210.5. In addition, in the example of FIG. 9, the power semiconductor device 200 may include a trench 244 as part of the creepage extension structure 240 for the power semiconductor package 200. The trench 244 may be defined along a peripheral edge of the housing 202 at the first side 202′ of the housing 202 between the electrical leads 210 and the thermal pad 230. The trench 244 may have a depth in a range of, for instance, 0.5 mm to about 2.0 mm.

As demonstrated by FIGS. 8 and 9, the power semiconductor packages according to example embodiments of the present disclosure may have a variety of different electrical lead options for the electrical leads. In this way, the power semiconductor packages according to aspects of the present disclosure are suitable for a variety of different types of semiconductor devices.

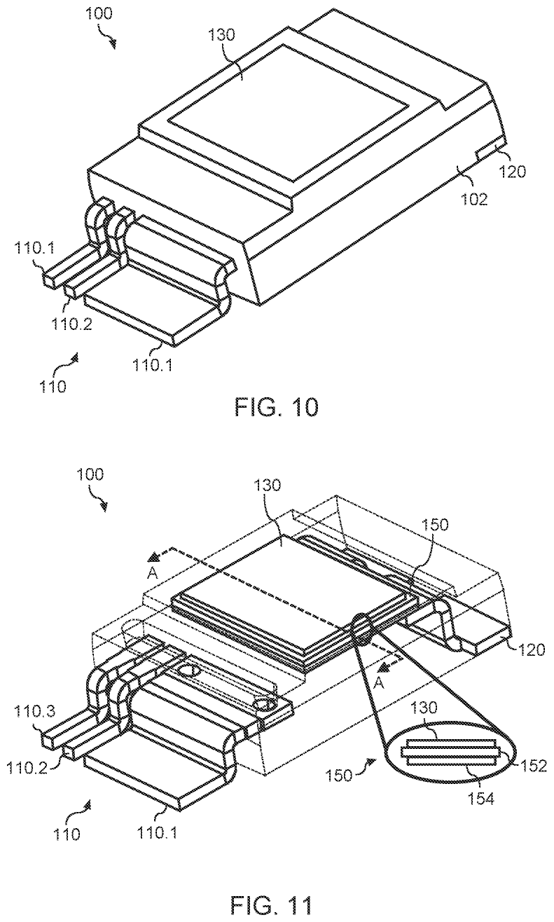

FIGS. 10 and 11 depicts a power semiconductor package 100 similar to the power semiconductor package 100 of FIGS. 1 and 2. In the example of FIGS. 10 and 11, the power semiconductor package 100 includes a different arrangement of electrical leads 110 relative to the power semiconductor package 100 of FIG. 1. The example power semiconductor package 100 of FIGS. 10 and 11 includes three electrical leads 110, namely a first lead 110.1, a second lead 110.2, and a third lead 110.3. The first lead 110.1 can have a larger size relative to the second lead 110.2, and third lead 110.3.

In addition, in the example power semiconductor package 100 of FIGS. 10 and 11, the thermal pad 130 is electrically isolated from SMT connection structures 120. More particularly, FIG. 11 depicts a top perspective view of the power semiconductor package 100 of FIG. 10 with the housing 102 transparent according to example embodiments of the present disclosure. As shown, the power semiconductor package 100 includes a mounting substrate 150 with an insulating layer 152.

FIG. 11 provides a cross-sectional view of the mounting substrate 150 taken along line A-A′. The thermal pad 130 is on the insulating layer 152. The insulating layer 152 may be formed from an insulating material, such as a ceramic material or other insulating material. The insulating substrate 152 may have a conductive layer 154 on a surface opposite the thermal pad 130. The conductive layer 154 may be electrically coupled to the SMT connection structures 120. The insulating layer 152 may provide electrical isolation between the thermal pad 130 and the SMT connection structures 120. In some examples, the mounting substrate 150 may be, for instance, a directed bonded copper (DBC) substrate or an active metal brazed (AMB) substrate.

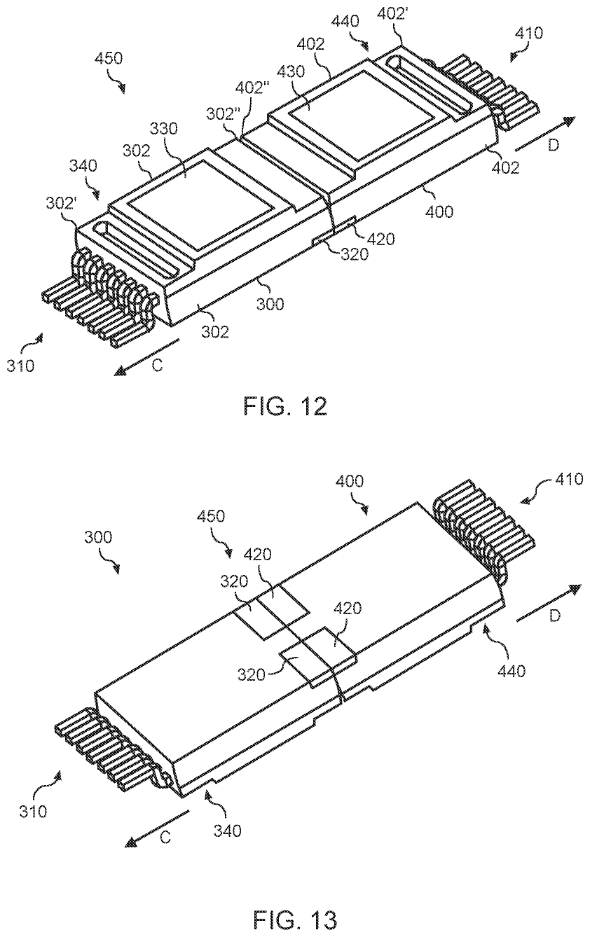

FIG. 12 depicts a top perspective view of a power semiconductor package assembly 450 according to example embodiments of the present disclosure. FIG. 13 depicts a bottom perspective view of a power semiconductor package assembly 450 according to example embodiments of the present disclosure. The power semiconductor package assembly 450 includes a first power semiconductor package 300 and a second power semiconductor package 400. Each of the first power semiconductor package 300 and the second power semiconductor package 400 may be similar to any of the power semiconductor packages described herein, such as the power semiconductor package 100 of FIG. 1.

For instance, the first power semiconductor package 300 may include a first housing 302 having a first side 302′ and a second side 302″ opposing the first side 302′. The first power semiconductor package 300 may include one or more first electrical leads 310 extending from the first side 302′. The first power semiconductor package 300 may include one or more first SMT connection structures 320 on the second side 302″. For instance, the first power semiconductor package 300 may include one or more first leadless SMT connection structures 320. The first leadless SMT connection structures 320 may be wettable flank connection structures. The first power semiconductor package 300 may include a first thermal pad 330. The first power semiconductor package 300 may include one or more first creepage extension structures 340. The one or more first creepage extension structures 340 may include a step structure and/or a trench. The power semiconductor package 300 may house a semiconductor die having one or more semiconductor devices, such as a MOSFET (e.g., a silicon carbide-based MOSFET) or a Schottky diode (e.g., a silicon carbide-based Schottky diode).

The second power semiconductor package 400 may include a first housing 402 having a third side 402′ and a fourth side 402″ opposing the third side 402′. The second power semiconductor package 400 may include one or more second electrical leads 410 extending from the third side 402′. The second power semiconductor package 400 may include one or more second SMT connection structures 420 on the fourth side 402″. For instance, the second power semiconductor package 400 may include one or more second leadless SMT connection structures 420. The second leadless SMT connection structures 420 may be wettable flank connection structures. The second power semiconductor package 400 may include a second thermal pad. The second power semiconductor package 400 may include one or more second creepage extension structures 440. The one or more second creepage extension structures 440 may include a step structure and/or a trench. The power semiconductor package 400 may house a semiconductor die having one or more semiconductor devices, such as a MOSFET (e.g., a silicon carbide-based MOSFET) or a Schottky diode (e.g., a silicon carbide-based Schottky diode).

As illustrated in FIGS. 12 and 13, the second side 302″ of the first power semiconductor package 300 is aligned with the fourth side 402″ of the second power semiconductor package 400. In this way, the one or more first leadless SMT connection structures 320 of the first power semiconductor package 300 are aligned with the one or more second leadless SMT connection structures 420 of the second power semiconductor package 400. The one or more first electrical leads 310 extend in a first direction C. The one or more second electrical leads 410 extend in a second direction D. The first direction C is opposite the second direction D. The power semiconductor package assembly 450 of FIGS. 12 and 13 may facilitate manufacturing of the power semiconductor packages according to example embodiments of the present disclosure.

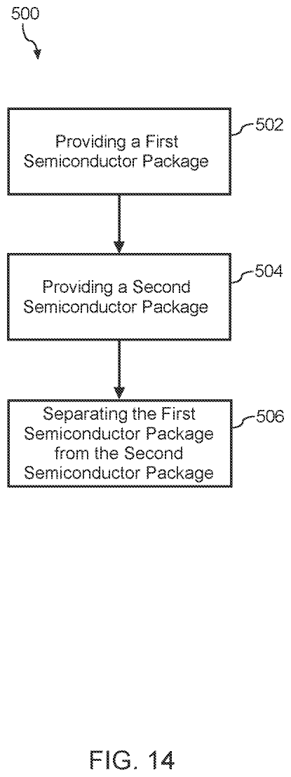

For instance, FIG. 14 depicts a flow diagram of an example method 500 according to example embodiments of the present disclosure. FIG. 14 depicts example process steps for purposes of illustration and discussion. Those of ordinary skill in the art, using the disclosures provided herein, will understand that process steps of any of the methods described in the present disclosure may be adapted, modified, include steps not illustrated, omitted, and/or rearranged without deviating from the scope of the present disclosure.

At 502, the method 500 may include providing a first power semiconductor package. For instance, the method may include providing the first power semiconductor package 300 of FIGS. 12 and 13. The first power semiconductor package 300 may include a first housing 302 having a first side 302′ and a second side 302″ opposing the first side 302′. The first power semiconductor package 300 may include one or more first electrical leads 310 extending from the first side 302′. The first power semiconductor package 300 may include one or more first SMT connection structures 320 on the second side 302″. For instance, the first power semiconductor package 300 may include one or more first leadless SMT connection structures 320. The first leadless SMT connection structures 320 may be wettable flank connection structures. The first power semiconductor package 300 may include a first thermal pad 330. The first power semiconductor package 300 may include one or more first creepage extension structures 340. The one or more first creepage extension structures 340 may include a step structure and/or a trench.

At 504 of FIG. 14, the method 500 may include providing a second power semiconductor package. The second power semiconductor package may include providing the second power semiconductor package 400 of FIGS. 12 and 13. The second power semiconductor package 400 may include a first housing 402 having a third side 402′ and a fourth side 402″ opposing the third side 402′. The second power semiconductor package 400 may include one or more second electrical leads 410 extending from the third side 402′. The second power semiconductor package 400 may include one or more second SMT connection structures 420 on the fourth side 402″. For instance, the second power semiconductor package 400 may include one or more second leadless SMT connection structures 420. The second leadless SMT connection structures 420 may be wettable flank connection structures. The second power semiconductor package 400 may include a second thermal pad. The second power semiconductor package 400 may include one or more second creepage extension structures 440. The one or more second creepage extension structures 440 may include a step structure and/or a trench.

In some examples, the second side of the first power semiconductor package may be aligned with the fourth side of the second power semiconductor package. For instance, as shown in FIGS. 12 and 13, the second side 302″ of the first power semiconductor package 300 is aligned with the fourth side 402″ of the second power semiconductor package 400. In this way, the one or more first leadless SMT connection structures 320 of the first power semiconductor package 300 are aligned with the one or more second leadless SMT connection structures 420 of the second power semiconductor package 400. The one or more first electrical leads 310 extend in a first direction C. The one or more second electrical leads 410 extend in a second direction D. The first direction C is opposite the second direction D.

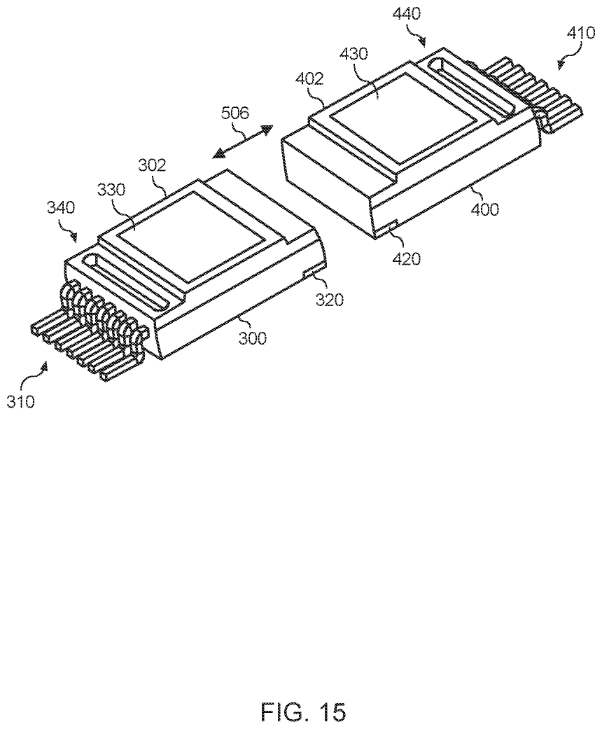

At 506 of FIG. 14, the method may include separating the first power semiconductor package from the second power semiconductor package. For instance, as shown in FIG. 15, the first power semiconductor package 300 may be separated from the second power semiconductor package 400 as indicated by the arrow representative of operation 506 of FIG. 14. In this way, the power semiconductor packages according to example embodiments of the present disclosure may be assembled in back-to-back fashion to provide the power semiconductor assembly. The power semiconductor packages may then be separated to provide individual power semiconductor packages.

Example aspects of the present disclosure are set forth below. Any of the below features or examples may be used in combination with any of the embodiments or features provided in the present disclosure.

One example aspect of the present disclosure is directed to a power semiconductor package. The power semiconductor package may include a power semiconductor die. The power semiconductor package may include a housing having a first side and a second side opposing the first side. The power semiconductor package may include one or more electrical leads extending from the first side. The power semiconductor package may include one or more leadless surface mount type (SMT) connection structures on the second side.

In some examples, the one or more leadless SMT connection structures each comprise a wettable flank connection structure. In some examples, the wettable flank connection structure is partially encapsulated by the housing such that a connection surface of the wettable flank connection structure is exposed through a mounting surface of the housing. In some examples, the wettable flank connection structure is exposed through at least one side surface of the housing.

In some examples, each of the one or more leadless SMT connection structures has a larger connection surface relative to each of the one or more electrical leads. In some examples, the power semiconductor package has a greater number of electrical leads on the first side relative to a number of leadless SMT connection structures on the second side. In some examples, the one or more electrical leads comprises a first lead and a second lead, wherein the first lead has a size that is greater than a size of the second lead.

In some examples, the housing comprises a first surface defined between the first side and the second side and a second surface opposing the first surface, wherein the first surface comprises at least one creepage extension structure, the at least one creepage extension structure comprising a step structure. In some examples, the at least one creepage extension structure comprises a first step structure between a thermal pad and the first side of the housing and a second step structure between the thermal pad and the second side of the housing. In some examples, the step structure has a depth of about 0.5 mm to about 2.0 mm. In some examples, the at least one creepage extension structure comprises a trench defined between the step structure and the one or more electrical leads.

In some examples, the power semiconductor package comprises a thermal pad that is electrically isolated from the one or more leadless SMT connection structures. In some examples, the thermal pad is on an insulating layer of a mounting substrate for the semiconductor die.

In some examples, the semiconductor die comprises a wide band gap semiconductor. In some examples, the semiconductor die comprises a metal-oxide-semiconductor field-effect-transistor (MOSFET), wherein a first lead of the one or more electrical leads is connected to a gate of the MOSFET and a second lead of the one or more electrical leads is connected to a source of the MOSFET. In some examples, the one or more leadless SMT connection structures are connected to a drain of the MOSFET. In some examples, a third lead of the one or more electrical leads is connected to a source-kelvin contact of the MOSFET or a sensor contact of the MOSFET. In some examples, the MOSFET comprises a silicon carbide-based MOSFET.

In some examples, the semiconductor die comprises a Schottky diode. In some examples, the one or more electrical leads are coupled to a first contact for the Schottky diode and the one or more SMT connection structures are coupled to a second contact for the Schottky diode. In some examples, the Schottky diode is a silicon carbide-based Schottky diode.

Another example aspect of the present disclosure is directed to a power semiconductor package. The power semiconductor package may include a semiconductor die. The power semiconductor package may include a housing having a first side and a second side opposing the first side. The power semiconductor package may include one or more electrical leads extending from the first side. The power semiconductor package may include one or more SMT connection structures on the second side. Each of the one or more SMT connection structures may have a connection surface area that is greater than a connection surface area of the one or more electrical leads.

In some examples, the connection surface area of each of the SMT connection structures is at least two times greater than the connection surface area of each of the one or more electrical leads.

In some examples, the one or more SMT connection structures each comprise a wettable flank connection structure. In some examples, the wettable flank connection structure is partially encapsulated by the housing such that a connection surface of the wettable flank connection structure is exposed through a mounting surface of the housing and such that the wettable flank connection structure is exposed through at least one side surface of the housing.

In some examples, each of the one or more SMT connection structures comprises an SMT connection tab extending from the second side of the housing. In some examples, each SMT connection tab extends from a side surface at the second side of housing at a location below a top surface of the housing.

In some examples, the power semiconductor package has a greater number of electrical leads on the first side relative to a number of SMT connection structures on the second side. In some examples, the one or more electrical leads comprises a first lead and a second lead, wherein the first lead has a size that is greater than a size of the second lead.

In some examples, the semiconductor die comprises a metal-oxide-semiconductor field-effect-transistor (MOSFET), wherein a first lead of the one or more electrical leads is connected to a gate of the MOSFET, a second lead of the one or more electrical leads is connected to a source of the MOSFET, and the one or more SMT connection structures are connected to a drain of the MOSFET. In some examples, the MOSFET comprises a silicon carbide-based MOSFET.

In some examples, the semiconductor die comprises a Schottky diode. In some examples, the one or more electrical leads are coupled to a first contact for the Schottky diode and the one or more SMT connection structures are coupled to a second contact for the Schottky diode. In some examples, the Schottky diode is a silicon carbide-based Schottky diode.

Another example aspect of the present disclosure is directed to a power semiconductor package. The power semiconductor package may include a semiconductor die. The power semiconductor package may include a housing having a first side and a second side opposing the first side. The housing having a first surface extending between the first side and the second side and a second surface opposing the first surface. The power semiconductor package may include a thermal pad. The power semiconductor package may include a step structure on the first surface of the housing. The step structure may be defined in the housing such that a first portion of the housing at the first side has a first thickness and a second portion of the housing at the thermal pad has a second thickness. The second thickness may be greater than the first thickness.

In some examples, the step structure is disposed between the thermal pad and the first side of the housing. In some examples, the first surface further comprises a trench defined between the step structure and the first side of the housing. In some examples, the step structure has a depth of about 0.5 mm to about 2.0 mm.

In some examples, the power semiconductor package comprises one or more electrical leads extending from the first side of the housing and one or more surface mount type (SMT) connection structures on the second side of the housing.

In some examples, the one or more SMT connection structures each comprise an SMT connection tab extending from the second side of the housing.

In some examples, the one or more SMT connection structure each comprise a wettable flank connection structure.

In some examples, the thermal pad is electrically isolated from the one or more SMT connection structures.

In some examples, the semiconductor die comprises a wide band gap semiconductor. In some examples, the semiconductor die comprises a metal-oxide-semiconductor field-effect-transistor (MOSFET). In some examples, the MOSFET is a silicon carbide-based MOSFET.

In some examples, the semiconductor die comprises a Schottky diode. In some examples, the Schottky diode is a silicon carbide-based Schottky diode.

Another example aspect of the present disclosure is directed to a method. The method may include providing a first power semiconductor package. The first power semiconductor package may include a first housing having a first side and a second side opposing the first side. The first power semiconductor package may include one or more first electrical leads extending from the first side, and one or more first leadless surface mount type (SMT) connection structures on the second side. The method may include providing a second power semiconductor package. The second power semiconductor package may include a second housing having a third side and a fourth side opposing the third side. The second power semiconductor package may include one or more second electrical leads extending from the third side, and one or more second leadless SMT connection structures on the fourth side. The second side of the first power semiconductor package may be aligned with the fourth side of the second power semiconductor package.

In some examples, the method further comprises separating the first power semiconductor package and the second power semiconductor package.

In some examples, the one or more first leadless SMT connection structures of the first power semiconductor package are aligned with the one or more second leadless SMT connection structures of the second power semiconductor package. In some examples, the one or more first SMT connection structures each comprise a wettable flank connection structure, and the one or more second SMT connection structures each comprise a wettable flank connection structure.

In some examples, the one or more first electrical leads extend in a first direction, the one or more second electrical leads extend in a second direction, the first direction being opposite the second direction.

In some examples, the first power semiconductor package comprises a first thermal pad and the second power semiconductor package comprises a second thermal pad.

In some examples, the first power semiconductor package comprises a first creepage extension structure that is part of the first housing, the first creepage extension structure comprising a first step structure, wherein the second power semiconductor package comprises a second creepage extension structure that is part of the second housing, the second creepage extension structure comprising a second step structure. In some examples, the first creepage extension structure comprises a first trench and the second creepage extension structure defines a second trench.

In some examples each of the first power semiconductor package and the second power semiconductor package comprise a wide band gap semiconductor die.

In some examples, the semiconductor die comprises a metal-oxide-semiconductor field-effect-transistor (MOSFET). In some examples, the MOSFET is a silicon carbide-based MOSFET.

In some examples, the semiconductor die comprises a Schottky diode. In some examples, the Schottky diode is a silicon carbide-based Schottky diode.

Another example aspect of the present disclosure is directed to a power semiconductor package assembly. The power semiconductor package assembly may include a first power semiconductor package. The first power semiconductor package may include a first housing having a first side and a second side opposing the first side. The first power semiconductor package may include one or more first electrical leads extending from the first side, and one or more first leadless surface mount type (SMT) connection structures on the second side. The power semiconductor package assembly may include a second power semiconductor package. The second power semiconductor package may include a second housing having a third side and a fourth side opposing the third side. The second power semiconductor package may include one or more second electrical leads extending from the third side, and one or more second leadless SMT connection structures on the fourth side. The second side of the first power semiconductor package may be aligned with the fourth side of the second power semiconductor package.

In some examples, the one or more first leadless SMT connection structures of the first power semiconductor package are aligned with the one or more second leadless SMT connection structures of the second power semiconductor package. In some examples, the one or more first leadless SMT connection structures each comprise a wettable flank connection structure, and the one or more second leadless SMT connection structure each comprise a wettable flank connection structure.

In some examples, the one or more first electrical leads extend in a first direction, the one or more second electrical leads extend in a second direction, the first direction being opposite the second direction.

In some examples, the first power semiconductor package comprises a first thermal pad and the second power semiconductor package comprises a second thermal pad.

In some examples, the first power semiconductor package comprises a first creepage extension structure that is part of the first housing, the first creepage extension structure comprising a first step structure, wherein the second power semiconductor package comprises a second creepage extension structure that is part of the second housing, the second creepage extension structure comprising a second step structure. In some examples, the first creepage extension structure comprises a first trench and the second creepage extension structure defines a second trench.

In some examples, ach of the first power semiconductor package and the second power semiconductor package comprise a wide band gap semiconductor die.

In some examples, the semiconductor die comprises a metal-oxide-semiconductor field-effect-transistor (MOSFET). In some examples, the MOSFET is a silicon carbide-based MOSFET.

In some examples, the semiconductor die comprises a Schottky diode. In some examples, the Schottky diode is a silicon carbide-based Schottky diode.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A power semiconductor package, comprising:
a semiconductor die;
a housing having a first side and a second side opposing the first side;
one or more electrical leads extending from the first side; and
one or more leadless surface mount type (SMT) connection structures on the second side.

2. The power semiconductor package of claim 1, wherein the one or more leadless SMT connection structures each comprise a wettable flank connection structure.

3. The power semiconductor package of claim 2, wherein the wettable flank connection structure is partially encapsulated by the housing such that a connection surface of the wettable flank connection structure is exposed through a mounting surface of the housing.

4. The power semiconductor package of claim 3, wherein the wettable flank connection structure is exposed through at least one side surface of the housing.

5. The power semiconductor package of claim 1, wherein each of the one or more leadless SMT connection structures has a larger connection surface relative to each of the one or more electrical leads.

6. The power semiconductor package of claim 1, wherein the power semiconductor package has a greater number of electrical leads on the first side relative to a number of leadless SMT connection structures on the second side.

7. The power semiconductor package of claim 1, wherein the one or more electrical leads comprise a first lead and a second lead, wherein the first lead has a size that is greater than a size of the second lead.

8. The power semiconductor package of claim 1, wherein the housing comprises a first surface defined between the first side and the second side and a second surface opposing the first surface, wherein the first surface comprises at least one creepage extension structure, the at least one creepage extension structure comprising a step structure.

9. The power semiconductor package of claim 8, wherein the at least one creepage extension structure comprises a first step structure between a thermal pad and the first side of the housing and a second step structure between the thermal pad and the second side of the housing.

10. The power semiconductor package of claim 8, wherein the step structure has a depth of about 0.5 mm to about 2.0 mm.

11. The power semiconductor package of claim 8, wherein the at least one creepage extension structure comprises a trench defined between the step structure and the one or more electrical leads.

12. The power semiconductor package of claim 1, further comprising a thermal pad that is electrically isolated from the one or more leadless SMT connection structures.

13. The power semiconductor package of claim 12, wherein the thermal pad is on an insulating layer of a mounting substrate for the semiconductor die.

14. (canceled)

15. The power semiconductor package of claim 1, wherein the semiconductor die comprises a metal-oxide-semiconductor field-effect-transistor (MOSFET), wherein a first lead of the one or more electrical leads is connected to a gate of the MOSFET and a second lead of the one or more electrical leads is connected to a source of the MOSFET, wherein the one or more leadless SMT connection structures are connected to a drain of the MOSFET.

16. (canceled)

17. The power semiconductor package of claim 15, wherein a third lead of the one or more electrical leads is connected to a source-kelvin contact of the MOSFET or a sensor contact of the MOSFET.

18. The power semiconductor package of claim 15, wherein the MOSFET comprises a silicon carbide-based MOSFET.

19. The power semiconductor package of claim 1, wherein the semiconductor die comprises a Schottky diode, wherein the one or more electrical leads are coupled to a first contact for the Schottky diode and the one or more SMT connection structures are coupled to a second contact for the Schottky diode.

20. (canceled)

21. The power semiconductor package of claim 19, wherein the Schottky diode is a silicon carbide-based Schottky diode.

22. A power semiconductor package, comprising:
a semiconductor die;
a housing having a first side and a second side opposing the first side;
one or more electrical leads extending from the first side;
one or more surface mount type (SMT) connection structures on the second side; and
wherein each of the one or more SMT connection structures has a connection surface area that is greater than a connection surface area of each of the one or more electrical leads.

23.-31. (canceled)

32. A power semiconductor package, comprising:
a semiconductor die;
a housing having a first side and a second side opposing the first side, the housing having a first surface extending between the first side and the second side and a second surface opposing the first surface;
a thermal pad on the first surface; and
a step structure on the first surface of the housing, the step structure defined in the housing such that a first portion of the housing at the first side has a first thickness and a second portion of the housing at the thermal pad has a second thickness, the second thickness being greater than the first thickness.

33.-69. (canceled)
